(19) United States
(12) Patent Application Publication
(10) Pub. No.: US 2007/0145857 A1
(43) Pub. Date: Jun. 28, 2007

(54) Electronic device with audio and haptic capability

(76) Inventors: David B. Cranfill, Antioch, IL (US); Hoi L. Young, Lake Villa, IL (US); Michael Bohan, Fox Lake, IL (US)

Correspondence Address: MOTOROLA INC, 600 NORTH US HIGHWAY 45, ROOM AS437, LIBERTYVILLE, IL, 60048-5343, US

(21) Appl. No.: 11/320,063

(22) Filed: Dec. 28, 2005

(51) Int. Cl. H01L 41/113

(52) U.S. Cl. 310/319

(57) ABSTRACT

An actuator (102), suitable for use with an electronic device, is provided. The actuator includes a thin-film sensor (104) and a transducer (106). The transducer is bonded to the thin-film sensor. The thin-film sensor is capable of sensing an input, and the transducer is capable of providing a tactile output in response to the input.

### FIELD OF THE INVENTION

This invention relates in general to electronic devices, and more specifically, to a navigation device with audio and haptic capabilities.

### BACKGROUND OF THE INVENTION

Electronic devices are used to perform complex input operations such as those required for playing games, playing audio files, browsing the Internet, and sending messages. In certain markets, there is pressure to produce more compact and smaller electronic devices. Moreover, additional navigational functions, for example, circular scrolling and Asian character entry, are being introduced in the electronic devices. However, implementing such navigational functions consume a lot of space in the electronic devices. For example, for a laptop computer, a standard mouse that provides navigational functions can become cumbersome and needs a lot of space to operate. Similarly, in mobile phones and portable video games, navigation devices such as joysticks and track balls occupy considerable space. As a result, compact navigation devices such as ‘touch screens’, which can be of different shapes and sizes, are used.

A touch screen can sense a tactile input and provide it to an electronic device. A variety of sensing technologies are available, including but not limited, to capacitive and resistive sensors. A user of the electronic device usually makes contact with the touch screen with a fingertip in order to move a cursor displayed in a graphical environment. A touch screen, however, also occupies a considerable amount of space on an electronic device.

### BRIEF DESCRIPTION OF THE FIGURES

The present invention is illustrated by way of example and not limitation in the accompanying figures, in which like references indicate similar elements, and in which:

FIG. 1 shows a cross-sectional view of an actuator, in accordance with a basic embodiment.

FIG. 2 shows a view of the actuator of FIG. 1, in accordance with a detailed embodiment.

FIG. 3 shows a view of a navigation device, in accordance with a basic embodiment.

FIG. 4 shows a top view of a navigation device, in accordance with a basic embodiment.

FIG. 5 shows a view of an electronic device, in accordance with a detailed embodiment.

Skilled artisans will appreciate that elements in the figures are illustrated for simplicity and clarity and have not necessarily been drawn to scale. For example, the dimensions of some of the elements in the figures may be exaggerated relative to other elements, to help to improve understanding of embodiments of the present invention.

### DETAILED DESCRIPTION

Before describing in detail the particular navigation device with audio and haptic capabilities in accordance with the present invention, it should be observed that the present invention resides primarily in combinations of method steps and apparatus components related to the navigation device with audio and haptic capabilities. Accordingly, the apparatus components have been represented where appropriate by conventional symbols in the drawings, showing only those specific details that are pertinent to understanding the present invention, so as not to obscure the disclosure with details that will be readily apparent to those of ordinary skill in the art having the benefit of the description herein.

Various embodiments provide a navigation device having haptic and audio output capabilities for use with an electronic device. Examples of electronic devices include Amplitude Modulation (AM)/Frequency Modulation (FM) radios, mobiles phones, computers, Personal Digital Assistants (PDAs), analog and digital audio devices, video games, remote controllers, and the like. The navigation device includes an actuator, which can be used to provide an input to the electronic device. Further, the actuator is capable of providing haptic and/or audio feedback in response to the input provided to the electronic device. In studying the ability to provide both tactile and acoustic feedback to the user, coupled with industry trends calling for more compact electronic devices, particularly in the area of thickness, the inventors sought to combine these functions into a single device.

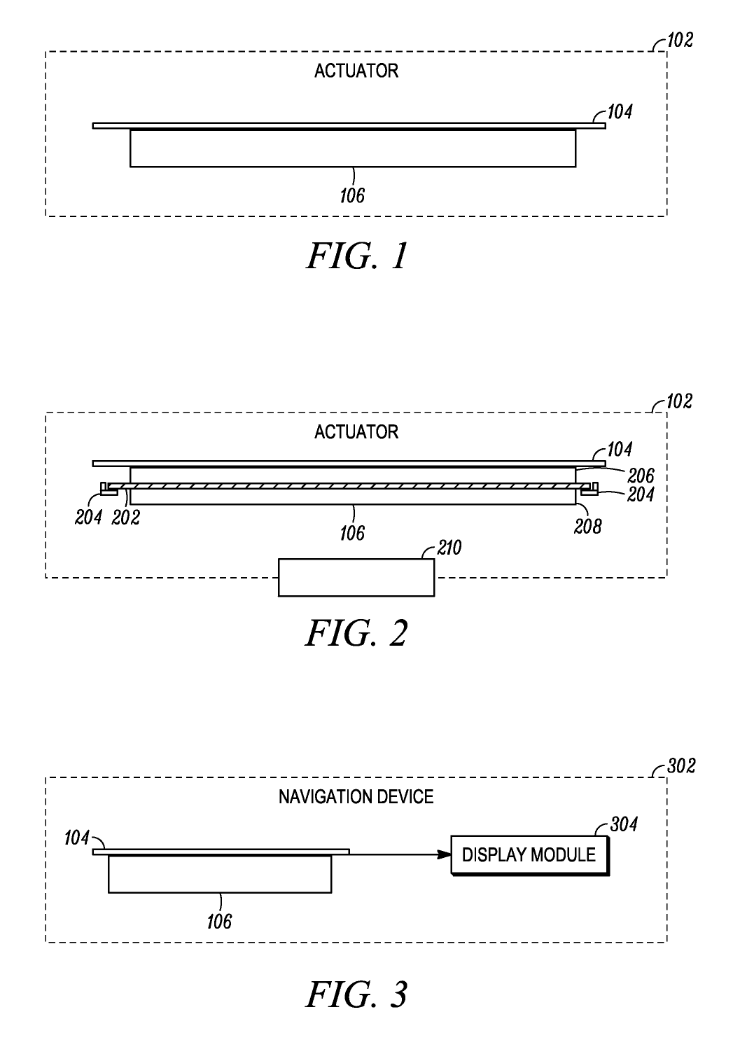

FIG. 1 shows a cross-section view of an actuator 102, in accordance with a basic embodiment. The actuator 102 includes a thin-film sensor 104 and a transducer 106. Examples of the thin-film sensor 104 include, but are not limited to, resistive touch-screen sensors, capacitive touch-screen sensors, or other thin-film sensor technologies. The thin-film sensor 104 can be manufactured to be less than 0.1 mm thick. An example of the transducer 106 includes, but is not limited to, a piezoelectric ceramic transducer. The transducer can be manufactured to be less than 0.3 mm thick. The transducer 106 is bonded to the thin-film sensor 104. An example of a bonding mechanism is an elastomeric adhesive or a thin-film pressure-sensitive adhesive (PSA).

The thin-film sensor 104 senses a tactile input provided by a user. In an embodiment, the thin-film sensor 104 includes one or more printed traces for providing directional functions to the user. Examples of the directional functions include, but are not limited to, scrolling up and scrolling down. The transducer 106 provides a tactile output in response to the input sensed by the thin-film sensor 104. The tactile output is an output that relates to a sense of touch, for example, vibrations. In an embodiment, the transducer 106 also provides an audio output. In this embodiment, the transducer 106 also functions as an audio output device, for example, a loud speaker.

FIG. 2 shows a view of the actuator 102 of FIG. 1, in accordance with a detailed embodiment. The actuator 102 includes the thin-film sensor 104, the transducer 106, and a suspension layer 202. In an embodiment, the suspension layer 202 is mounted on a mounting frame 204 that provides tension to the suspension layer and a means of mounting the actuator to the housing of the electronic device. The transducer 106 includes a first transducer layer 206 and a second transducer layer 208. The suspension layer 202 provides mechanical support to the transducer layers 206 and 208. The thin-film sensor 104 is coupled to the transducer 106 above the first transducer layer 206, as shown in FIG. 2 and optionally can be bonded to the mounting frame 204.

The thin-film sensor 104 senses a tactile input provided by the user. In an embodiment, the user touches the thin-film sensor 104 with a fingertip to provide the input. The suspension layer 202 is sandwiched between the first transducer layer 206 and the second transducer layer 208. The first transducer layer 206 is bonded to a first side of the suspension layer 202 while the second transducer layer 208 is bonded to an opposing second side of the suspension layer 202. The first transducer layer 206 and the second transducer layer 208 of the transducer 106 are bonded with the suspension layer 202 by using an adhesive. Examples of the adhesive include, but are not limited to, various elastomeric adhesives, resin-based adhesives, and Pressure Sensitive Adhesive (PSA) films. This arrangement enables the first transducer layer 206, for example, to contract, and the second transducer layer 208, for example, to expand, in response to electrical signals from, for example, an electronic device (not shown in FIG. 2). As a result, the transducer 106 vibrates to enable the transducer 106 to act as an audio and/or tactile output device.

Whether the transducer 106 acts as an audio output device or a tactile output device depends on the mechanical resonant frequency of the transducer 106. The acoustic output of the device falls off dramatically below the fundamental resonant frequency, similar to a traditional loudspeaker. However, there is sufficient motion below this frequency to impart distinct tactile sensation to a user's finger. For example, tactile or haptic output is created when the transducer 106 is driven to vibrate at lower frequencies, such as 70-400 Hz. Meanwhile, audio output is created when the transducer 106 is driven to vibrate at higher frequencies, such as 600-20,000 Hz. Alternating lower driving frequencies with higher driving frequencies allows the transducer 106 to act as both an audio output device and a tactile output device. The resonant frequency of the transducer 106 is governed by the mass and the mechanical compliance of the transducer/sensor combination. These values may be tuned to provide a resonant frequency above the range desired for haptic input, typically targeted at the desired lower end of the desired audio frequency range. In an embodiment, the suspension layer 202 is metallic and capable of providing an electrical input to the actuator 102, as well a providing the bulk of the required mechanical compliance.

The transducer 106 provides the tactile feedback in response to the input sensed by the thin-film sensor 104. In an embodiment, the actuator 102 also includes a backstop 210. The backstop prevents overstrain on the transducer 106 if the actuator 102 is dropped or subjected to an aggressive user.

FIG. 3 shows a view of a navigation device 302, in accordance with a basic embodiment. The navigation device 302 includes the thin-film sensor 104, the transducer 106, and a display module 304. In an embodiment, the navigation device 302 is used with an electronic device (not shown in FIG. 3). The thin-film sensor 104 is bonded to the transducer 106 and provides an input from the user to the electronic device. In an embodiment, the thin-film sensor 104 includes one or more printed traces. The one or more printed traces provide an electrical signal corresponding to the input provided by the user to the electronic device. For example, the thin film can have a character printed on it. When the user touches the character, electrical signals corresponding to the character are generated by the corresponding printed traces and are provided to the electronic device. In another example, an array of traces can be created to track the motion of a finger across the surface of transducer 104, again with the corresponding electrical signals reported to the electronic device.

The transducer 106 then provides a vibrotactile output in response to the input provided by the thin-film sensor 104. The vibrotactile output is an output that relates to the sense of touch, for example, vibrations. In an embodiment, the thin-film sensor 104 is operatively coupled with the display module 304, for example, a liquid crystal display. The display module 304 provides a visual feedback in response to the input provided through the thin-film sensor 104. For example, the display module 304 may display the character, which is provided as an input to the electronic device through the thin-film sensor 104.

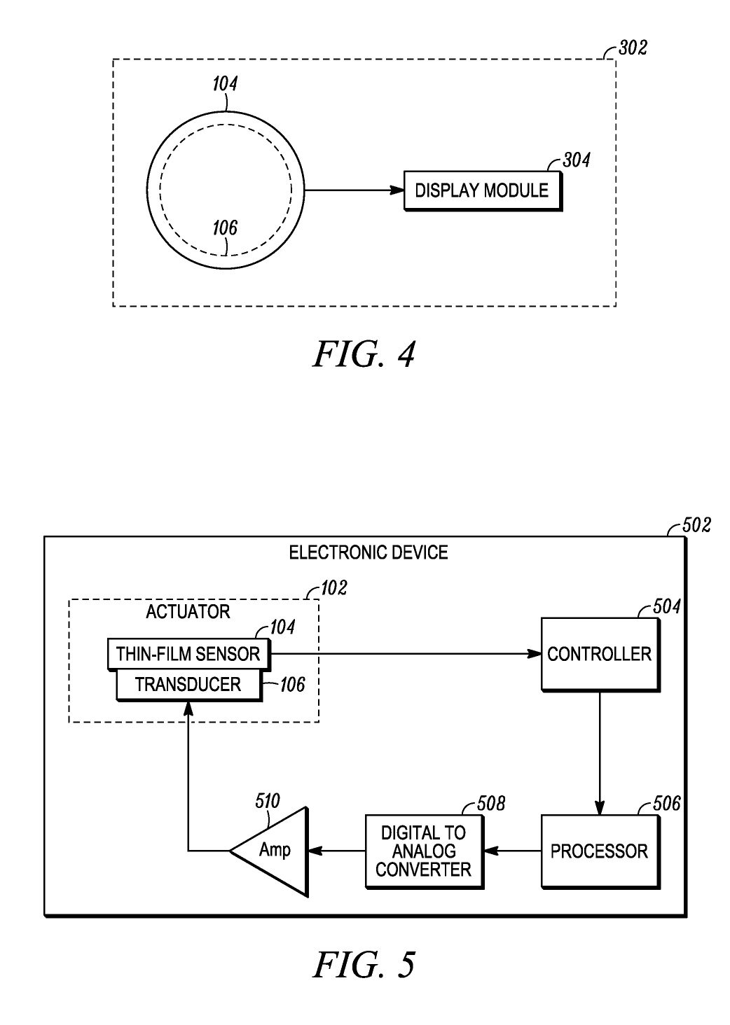

FIG. 4 shows a top view of the navigation device 302, in accordance with a basic embodiment. As shown in the top view, the thin-film sensor 104 is implemented as a circular touch pad and the transducer 106 is a circular transducer. Other touch pad and transducer shapes are possibly and limited by acoustic and mechanical constraints.

FIG. 5 shows a view of an electronic device 502, in accordance with a detailed embodiment. The electronic device 502 includes the actuator 102, a controller 504, a processor 506, a digital to analog converter 508, and a power amplifier 510. Examples of the electronic device 502 include, but are not limited to, mobile phones, remote controllers, video game controllers, laptops, and Personal Digital Assistants (PDAs). The actuator 102 includes the thin-film sensor 104 and the transducer 106.

The thin-film sensor 104 is bonded with the transducer 106. The thin-film sensor 104 senses the input provided by the user and provides it to the controller 504. The controller 504 includes an analog to digital converter (not shown in FIG. 4) that converts the input into a digital signal and provides it to the processor 506. In an embodiment, the controller 504 provides a hardware interface for peripheral devices connected to or incorporated within the electronic device 502. The processor 506 processes the digital signal and accepts the corresponding input. Further, in response to the digital signal received by the processor 506, the processor 506 provides feedback to drive the transducer in order to provide a tactile sensation. One embodiment uses a digital to analog converter 508, which converts the digital feedback into an analog feedback. The analog feedback is then provided to the power amplifier 510, which amplifies the analog feedback and provides it to the transducer 106. The transducer 106 then provides a tactile and/or audio output in response to the input sensed by the thin-film sensor 104.

The vibrational frequency of the transducer 106 determines whether the transducer 106 acts as an audio output device or a tactile output device. For example, tactile or haptic output is created when the transducer 106 is driven to vibrate at lower frequencies, such as 70-400 Hz. Meanwhile, audio output is created when the transducer 106 is driven to vibrate at higher frequencies, such as 600-20,000 Hz. Alternating lower driving frequencies with higher driving frequencies allows the transducer 106 to act as both an audio output device and a tactile output device.

In an embodiment, the processor 506 processes a digital audio signal received from a peripheral device such as an audio player (not shown in FIG. 4) in the electronic device 502. The processor 506 processes the digital audio signal and provides it to the digital to analog converter 508, which converts the digital audio signal into an analog audio signal. Next, the digital to analog converter 508 provides the analog audio signal to the amplifier 510. The amplifier 510 amplifies the analog audio signal and provides it to the transducer 106. The transducer 106 then vibrates according to the analog audio signal, and provides the corresponding audio output. In other words, the transducer 106 functions as an audio loud speaker.

Various embodiments, as described above, provide an actuator that is suitable for operation in electronic devices with small thickness. The actuator provides an input to an electronic device through a thin-film sensor. The actuator also provides a haptic output in response to the input provided. The haptic output confirms to the user of the electronic device that the input has been sensed. In addition, the actuator can be used to provide an audio output in response to an audio signal received from the electronic device.

It will be appreciated that the electronic device described herein may include of one or more conventional processors and unique stored program instructions that control the one or more processors, to implement, in conjunction with certain non-processor circuits, some of the functions of the electronic device described herein. The non-processor circuits may include, but are not limited to, a radio receiver, a radio transmitter, signal drivers, clock circuits, power source circuits, and user input devices.

It is expected that one of ordinary skill, notwithstanding possible significant effort and many design choices, motivated by, for example, the available time, current technology and economic considerations, when guided by the concepts and principles disclosed herein, will be readily capable of manufacturing a device in accordance with the description, as set out above.

In this document, relational terms such as first and second, and the like may be used solely to distinguish one entity or action from another entity or action without necessarily requiring or implying any actual such relationship or order between such entities or actions. The terms ‘comprises,’ ‘comprising,’ or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by ‘comprises . . . a’ or ‘comprising . . . a’, does not, without more constraints, preclude the existence of additional identical elements in the process, method, article, or apparatus that comprises the element.

The term ‘another’, as used herein, is defined as at least a second or more. The terms ‘including’ and/or ‘having’, as used herein, are defined as comprising. The terms ‘including’ and/or ‘having’, as used herein, are defined as comprising. The term ‘coupled’, as used herein with reference is defined as connected, although not necessarily directly, and not necessarily mechanically.

In the foregoing specification, the invention and its benefits and advantages have been described with reference to specific embodiments. However, one of ordinary skill in the art would appreciate that various modifications and changes can be made without departing from the scope of the present invention, as set forth in the claims. Accordingly, the specification and figures are to be regarded in an illustrative rather than a restrictive sense, and all such modifications are intended to be included within the scope of the present invention. The benefits, advantages, solutions to problems, and any element(s) that may cause any benefit, advantage or solution to occur or become more pronounced are not to be construed as critical, required or essential features or elements of any or all the claims. The invention is defined solely by the appended claims, including any amendments made during the pendency of this application, and all equivalents of the claims, as issued.

What is claimed is:

1. An actuator comprising:
a thin-film sensor; and
a transducer bonded to the thin-film sensor, wherein the transducer is capable of providing a tactile output.

2. The actuator of claim 1, wherein the transducer comprises:
a first transducer layer bonded to a first side of a suspension layer; and
a second transducer layer bonded to a second side of the suspension layer.

3. The actuator of claim 1, wherein the transducer is further capable of providing an audio output.

4. The actuator of claim 1, wherein the transducer is a piezoelectric ceramic transducer.

5. The actuator of claim 1, wherein the thin-film sensor comprises one or more printed traces, the one or more printed traces for providing directional functions.

6. The actuator of claim 1, wherein the thin-film sensor is one from a group of: a resistive touch-screen sensor and a capacitive touch-screen sensor.

7. The actuator of claim 2 further comprising:
a mounting frame coupled to the suspension layer.

8. The actuator of claim 7, wherein the mounting frame is further coupled to the thin-film sensor.

9. A navigation device for use with an electronic device, the navigation device comprising:
a thin-film sensor capable of providing an input to the electronic device; and
a transducer bonded to the thin-film sensor, wherein the transducer is capable of providing a vibrotactile output, in response to the input, and an audio output.

10. The navigation device of claim 9, wherein the thin-film sensor comprises one or more printed traces for providing the input to the electronic device.

11. The navigation device of claim 9, further comprising a display module to provide a visual feedback in response to the input provided through the thin-film sensor.

12. An electronic device comprising:
an actuator, the actuator comprising:
a thin-film sensor, wherein the thin-film sensor is capable of providing an input to the electronic device; and
a piezoelectric transducer bonded to the thin-film sensor, wherein the piezoelectric transducer is capable of providing a tactile feedback in response to the input; and
an electronic circuit coupled to the actuator, the electronic circuit capable of providing an analog signal to the piezoelectric transducer to generate the tactile feedback.

13. The electronic device of claim 12, wherein the electronic circuit comprises:
a controller capable of receiving the input and converting the input to a digital signal;
a processor coupled to the first controller, the processor capable of processing the digital signal;
a digital to analog converter coupled to the processor, the digital to analog converter capable of converting the digital signal into the analog signal; and
an amplifier coupled to the digital to analog converter, the amplifier capable of amplifying the analog signal.

14. The electronic device of claim 13, wherein the piezoelectric transducer is further capable providing an audio output, wherein the electronic circuit is capable of providing an electric signal to generate the audio output.

15. The electronic device of claim 14, wherein the processor is further capable of generating the electric signal, wherein the electrical signal is converted into an audio signal by the digital to analog converter.

16. The electronic device of claim 15, wherein the audio signal is amplified by the amplifier.

17. The electronic device of claim 13, wherein the controller includes an analog to digital converter for converting the input to the digital signal.
